(19) United States
(12) Patent Application Publication
(10) Pub. No.: US 2021/0159467 A1
(43) Pub. Date: May 27, 2021

(54) METHOD OF MANUFACTURING LIGHT-EMITTING DEVICE

(71) Applicant: Shenzhen China Star Optoelectronics Semiconductor Display Technology Co., Ltd., Shenzhen, Guangdong (CN)

(72) Inventors: Yongwei WU, Shenzhen (CN); Chiayu LEE, Shenzhen (CN); Chunche HSU, Shenzhen (CN); Shujhih CHEN, Shenzhen (CN); Bo HE, Shenzhen (CN); Pei JIANG, Shenzhen (CN); Yongming YIN, Shenzhen (CN); Miao DUAN, Shenzhen (CN)

(73) Assignee: Shenzhen China Star Optoelectronics Semiconductor Display Technology Co., Ltd., Shenzhen, Guangdong (CN)

(21) Appl. No.: 16/642,032

(22) PCT Filed: Dec. 3, 2019
(86) PCT No.: PCT/CN2019/122811

§ 371 Date: Feb. 26, 2020

(30) Foreign Application Priority Data
Nov. 26, 2019 (CN) 201911170021.7

(51) Int. Cl. H01L 51/56; H01L 51/00

(52) U.S. Cl. CPC H01L 51/56; H01L 51/0007; H01L 51/0072; H01L 51/0017; H01L 51/0026; H01L 51/001

(57) ABSTRACT

An embodiment of the present invention discloses a method of manufacturing a light-emitting device. In an embodiment of the present invention, a method of manufacturing a light-emitting device is provided. Because the electron transport layer is prepared by solution processing, compared with the traditional vacuum evaporation coating, it can use a simpler equipment and a simpler process, and have a higher material utilization rate, which effectively improves the preparation effectiveness of the light-emitting device.

### BACKGROUND OF INVENTION

The present application claims priority to Chinese patent application no. 201911170021.7 submitted to Chinese Patent Office on Nov. 26, 2019, entitled “METHOD OF MANUFACTURING LIGHT-EMITTING DEVICE”, the entire contents of which are incorporated herein by reference.

### Field of the Invention

The present invention relates to a field of display technology, and in particular, to a method of manufacturing a light-emitting device.

### Description of Prior Art

At present, as a new generation of semiconductor materials, a material based on a perovskite structure has shown a great application potential in a field of optoelectronic devices such as solar cells, displays, lighting, lasers and detectors. For a perovskite light-emitting diode (PeLED) for organic light-emitting diode (OLED) light emission, the perovskite material has the characteristics of high efficiency, high brightness, and high color purity, etc., perfectly meeting requirements of high-end display applications.

In order to improve efficiency of a device, the perovskite light-emitting diode usually adopts a multilayered device structure, and a hole transport layer and an electron transport layer are arranged between the perovskite light-emitting layer and a cathode and between the perovskite light-emitting layer and an anode. 2,9-dimethyl-4,7-biphenyl-1,10-ortho-diazaphenanthrene (Bathocuproin, a hole blocking material) is a common material of the electron transport layer, due to its high electron mobility (10 cm²/V.s to 10⁻³ cm²/V.s), energy levels of a lowest unoccupied molecular orbital (LUMO) (˜−3.0 eV) and a highest occupied molecular orbital (HOMO) (−6.4 eV), and is widely used in organic light-emitting diodes, quantum dot light-emitting diodes, perovskite light-emitting diodes and other optoelectronic devices.

However, 2,9-dimethyl-4,7-biphenyl-1,10-o-diazaphenanthrene used for OLED light emission is usually prepared by vacuum evaporation coating. This manufacturing method not only has high equipment requirements, but also has serious waste of materials and complicated processes during the manufacturing, resulting in a significant increase in cost.

### SUMMARY OF INVENTION

The embodiment of the present invention provides a method of manufacturing a light-emitting device, which is used to solve the problem that the diode device of the prior art using 2,9-dimethyl-4,7-biphenyl-1,10-o-diazaphenanthrene is usually manufactured by vacuum evaporation coating, which not only requires high equipment, but also causes serious waste of materials and complicated processes during the manufacturing, resulting in a significant increase in cost.

In order to solve the above problems, in a first aspect, the present application provides a method of manufacturing a light-emitting device, and the method includes: forming a pixel electrode on a substrate; forming a hole transport layer on the pixel electrode; forming a light-emitting layer on the hole transport layer; forming an electron transport layer on the light-emitting layer by coating a saturated solution of 2,9-dimethyl-4,7-biphenyl-1,10-o-diazaphenanthrene; and forming a common electrode on the electron transport layer.

Further, the step of forming an electron transport layer on the light-emitting layer by coating a saturated solution of 2,9-dimethyl-4,7-biphenyl-1,10-o-diazaphenanthrene includes:

forming a first spin-coating layer on the light-emitting layer by spin-coating the 2,9-dimethyl-4,7-biphenyl-1,10-o-diazaphenanthrene saturated solution in a spin-coating equipment; and

annealing the first spin-coating layer to form the electron transport layer.

Further, during the process of spin-coating the 2,9-dimethyl-4,7-biphenyl-1,10-o-diazaphenanthrene saturated solution in a spin-coating equipment, the spin-coating equipment adopts a rotation speed of 2500-4000 times per minute and a processing time of 30-90s.

Further, the step of annealing the first spin-coating layer to form the electron transport layer includes:

placing the first spin-coating in an environment of 80 to 150° C. for annealing for 10 to 15 minutes to form the electron transport layer.

Further, a solvent of the saturated solution of 2,9-dimethyl-4,7-biphenyl-1,10-o-diazaphenanthrene is isopropanol, ethanol or toluene.

Further, the step of forming a pixel electrode on a substrate further includes:

etching the pixel electrode to form a pixel electrode pattern.

Further, the step of forming a hole transport layer on the pixel electrode includes:

forming a second spin-coating layer on the pixel electrode by spin-coating a solution of poly(3,4-ethylenedioxythiophene)-poly(styrenesulfonic acid) on the pixel electrode in a spin-coating equipment; and

annealing the second spin-coating layer to form the hole transport layer.

Further, during the process of spin-coating a solution of poly(3,4-ethylenedioxythiophene)-poly(styrenesulfonic acid) on the pixel electrode in a spin-coating equipment, the spin-coating equipment adopts a rotation speed of 2500-4000 times per minute and a processing time of 40-80s.

Further, the step of annealing the second spin-coating layer to form the hole transport layer includes:

placing the second spin-coating in an environment of 120-160° C. for annealing for 15 to 30 minutes to form the hole transport layer.

Further, the step of forming a light-emitting layer on the hole transport layer includes:

forming a third spin-coating layer on the hole transport layer by spin-coating a perovskite precursor solution in a spin-coating equipment; and

annealing the third spin-coating to form the light-emitting layer.

Further, during the process of spin-coating a perovskite precursor solution in a spin-coating equipment, the spin-coating equipment adopts a rotation speed of 2500-5000 times per minute and a processing time of 50-120s.

Further, the step of annealing the third spin-coating layer to obtain the light-emitting layer includes:

placing the third spin-coating layer in an environment of 80-120° C. for annealing for 10-60 minutes to form the light-emitting layer.

Further, the step of forming a common electrode on the electron transport layer includes:

forming the common electrode on the electron transport layer by vacuum evaporation coating aluminum/lithium fluoride.

Further, in the common electrode, a thickness of lithium fluoride is 1 nm, and a thickness of aluminum is 90-120 nm.

In a second aspect, the present application provides a light-emitting device; the light-emitting device is obtained by using the method of manufacturing the light-emitting device described above.

In a third aspect, the present application provides a light-emitting device, which includes the light-emitting device described above.

In a fourth aspect, the present application provides a method of manufacturing a light-emitting device, the method including:

forming a pixel electrode on a substrate;

forming a hole transport layer on the pixel electrode;

forming a light-emitting layer on the hole transport layer;

forming a first spin-coating layer on the light-emitting layer by spin-coating a 2,9-dimethyl-4,7-biphenyl-1,10-o-diazaphenanthrene saturated solution in a spin-coating equipment; and

placing the first spin-coating in an environment of 80 to 150° C. for annealing for 10 to 15 minutes to form an electron transport layer.

Further, a solvent of the saturated solution of 2,9-dimethyl-4,7-biphenyl-1,10-o-diazaphenanthrene is isopropanol, ethanol or toluene.

Further, the step of forming a pixel electrode on a substrate further includes:

etching the pixel electrode to form a pixel electrode pattern.

Further, the step of forming a hole transport layer on the pixel electrode includes:

forming a second spin-coating layer on the pixel electrode by spin-coating a solution of poly(3,4-ethylenedioxythiophene)-poly(styrenesulfonic acid) on the pixel electrode in a spin-coating equipment; and

annealing the second spin-coating layer to form the hole transport layer.

Further, the step of annealing the second spin-coating layer to obtain the hole transport layer includes:

placing the second spin-coating in an environment of 120-160° C. for annealing for 15 to 30 minutes to form the hole transport layer.

Further, the step of forming a light-emitting layer on the hole transport layer includes:

forming a third spin-coating layer on the hole transport layer by spin-coating a perovskite precursor solution in a spin-coating equipment; and

annealing the third spin-coating to form the light-emitting layer.

Further, the step of annealing the third spin-coating layer to obtain the light-emitting layer includes:

placing the third spin-coating layer in an environment of 80-120° C. for annealing for 10-60 minutes to form the light-emitting layer.

Further, the step of forming a common electrode on the electron transport layer includes:

forming the common electrode on the electron transport layer by vacuum evaporation coating aluminum or lithium fluoride.

Advantageous effects: In an embodiment of the present invention, a method of manufacturing a light-emitting device is provided. The method includes: forming a pixel electrode on a substrate; forming a hole transport layer on the pixel electrode; forming a light-emitting layer on the hole transport layer; forming an electron transport layer on the light-emitting layer by coating a saturated solution of 2,9-dimethyl-4,7-biphenyl-1,10-o-diazaphenanthrene; and forming a common electrode on the electron transport layer. Because the electron transport layer is prepared by solution processing, compared with the traditional vacuum evaporation coating, it can use a simpler equipment and a simpler process, and have a higher material utilization rate, which effectively improves the preparation effectiveness of the light-emitting device.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic flowchart of a method of manufacturing a light-emitting device according to an embodiment of the present invention.

FIG. 2 is a schematic structural diagram of a light-emitting device according to an embodiment of the present invention.

### DETAILED DESCRIPTION OF PREFERRED EMBODIMENTS

Please refer to the figures in the drawings, in which, like numbers refer to like elements throughout the description of the figures. Hereinafter, the present invention will be described in further detail with reference to examples. It is to be understood, however, that these examples are for illustrative purposes only and are not intended to limit the scope of the present invention.

In the description of the present invention, it is to be understood that the terms “center”, “longitudinal”, “transverse”, “length”, “width”, “thickness”, “upper”, “lower”, “front”, “post”, “left”, “right”, “vertical”, “horizontal”, “top”, “bottom”, “inside”, “outside”, etc. demonstrating the orientation or positional relationship of the indications is based on the orientation shown in the drawings Or, the positional relationship is merely for the convenience of the description of the present invention and the simplification of the description, and is not intended to imply that the device or the component of the present invention has a specific orientation and is constructed and operated in a specific orientation, thus being not to be construed as limiting the present invention. Moreover, the terms “first” and “second” are used for descriptive purposes only and are not to be construed as indicating or implying a relative importance or not to implicitly indicate a number of technical features indicated. Thus, features defined by “first” or “second” may include one or more of the described features either explicitly or implicitly. In the description of the present invention, the meaning of “a plurality” is two or more unless specifically defined otherwise.

The diode device of the prior art using 2,9-dimethyl-4,7-biphenyl-1,10-o-diazaphenanthrene is usually manufactured by vacuum evaporation coating, which causes the technical problems of not only a high equipment requirement, but also serious waste of materials and complicated processes during the manufacturing, resulting in a significant increase in cost.

In view of this, embodiments of the present invention provide a method of manufacturing a light-emitting device, a light-emitting device, and a display panel, which are described in detail below, respectively.

First, a method of manufacturing a light-emitting device is provided by an embodiment of the present invention. The method includes: forming a pixel electrode on a substrate; forming a hole transport layer on the pixel electrode; forming a light-emitting layer on the hole transport layer; forming an electron transport layer on the light-emitting layer by coating a saturated solution of 2,9-dimethyl-4,7-biphenyl-1,10-o-diazaphenanthrene; and forming a common electrode on the electron transport layer.

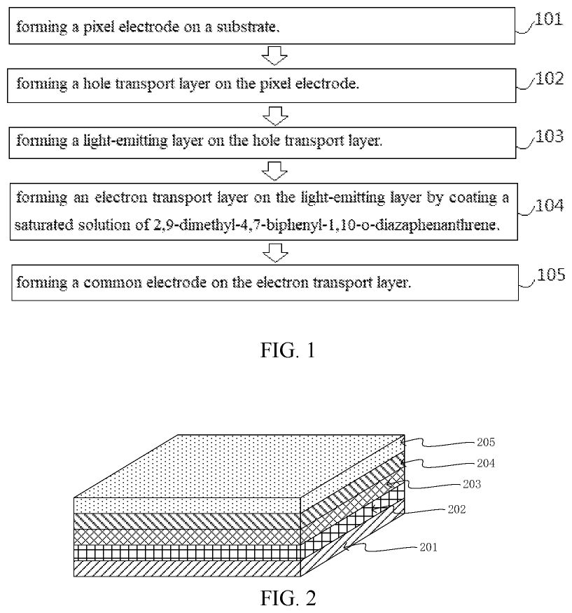

As shown in FIG. 1, it is a schematic flowchart of a method of manufacturing a light-emitting device according to an embodiment of the present invention, where the method includes the followings.

In general, organic electroluminescence employs photoelectric functional characteristics of organic semiconductor materials to directly convert electrical energy into light energy. Organic light-emitting diodes (OLEDs) are carrier-injection type, wherein holes injected from an anode and electrons injected from a cathode are combined to form excitons in the light-emitting layer, and release energy in a form of light energy. During this period, a series of physical processes including carrier injection and migration, and exciton formation and diffusion are involved.

The light-emitting device may be a flexible OLED, a rigid OLED, or a transparent OLED, and the type of the light-emitting device is not particularly limited in the present application, and it depends on actual situations.

101. forming a pixel electrode on a substrate.

The pixel electrode is the anode described above, and the pixel electrode is indium tin oxide (ITO).

102. forming a hole transport layer on the pixel electrode.

103. forming a light-emitting layer on the hole transport layer.

Specifically, the embodiments of the present invention are mainly directed to a perovskite light-emitting diode, that is, a light-emitting layer made of a perovskite material.

Generally, the perovskite structure has a general formula expressed as ABO3, and has a cubic crystal structure, which is a kind of composite metal oxide. A typical perovskite structural material is CaTiO₃.

104. forming an electron transport layer on the light-emitting layer by coating a saturated solution of 2,9-dimethyl-4,7-biphenyl-1,10-o-diazaphenanthrene.

In the above, the present invention prepares an electron transport layer by solution processing, and specifically, by spin-coating.

105. forming a common electrode on the electron transport layer.

The common electrode is the cathode described above.

In an embodiment of the present invention, a method of manufacturing a light-emitting device is provided. The method includes: forming a pixel electrode on a substrate; forming a hole transport layer on the pixel electrode; forming a light-emitting layer on the hole transport layer; forming an electron transport layer on the light-emitting layer by coating a saturated solution of 2,9-dimethyl-4,7-biphenyl-1,10-o-diazaphenanthrene; and forming a common electrode on the electron transport layer. Because the electron transport layer is prepared by solution processing, compared with the traditional vacuum evaporation coating, it can use a simpler equipment and a simpler process, and have a higher material utilization rate, which effectively improves the preparation effectiveness of the light-emitting device.

On the basis of the above embodiment, in another specific embodiment of the present application, the step of forming an electron transport layer on the light-emitting layer by coating a saturated solution of 2,9-dimethyl-4,7-biphenyl-1,10-o-diazaphenanthrene includes:

forming a first spin-coating layer on the light-emitting layer by spin-coating the 2,9-dimethyl-4,7-biphenyl-1,10-o-diazaphenanthrene saturated solution in a spin-coating equipment.

The 2,9-dimethyl-4,7-biphenyl-1,10-o-phenanthroline is widely used in organic light emitting diodes, quantum dot light-emitting diodes, perovskite light-emitting diodes, and other optoelectronic devices, due to its high electron mobility (10-4 cm2/V.s to 10-3 cm2/V.s), deep energy levels of a lowest unoccupied molecular orbital (LUMO) (˜−3.0 eV) and a highest occupied molecular orbital (HOMO) (−6.4 eV).

In an embodiment of the present application, the spin-coating is performed by: placing the dilute solution to be coated on a flat bottom plate, and starting to rotate the spinner with the bottom plate from slow to fast, wherein the dilute solution on the bottom plate is coated into a thin film due to the centrifugal force. A thickness of the spin-coated film can achieve a range from micron to nanometer. This is a common method of making thin and uniform polymer films on a flat bottom plate and making thin films in the microelectronics industry.

The first spin-coating is annealed to prepare the electron transport layer.

In an embodiment of the present application, when the spin-coated solution forms the first spin-coating layer, the solvent in the first spin-coating layer needs to be removed. In order to improve the preparation efficiency, an annealing process can be used to make the solvent in the first spin-coating layer quickly volatilize or evaporate, but the premise is to ensure that the temperature during annealing does not impact the properties of the organic material in the spin-coating layer.

Based on the above embodiment, in another specific embodiment of the present application, during the process of spin-coating the 2,9-dimethyl-4,7-biphenyl-1,10-o-diazaphenanthrene saturated solution in a spin-coating equipment, the spin-coating equipment adopts a rotation speed of 2500-4000 times per minute and a processing time of 30-90s.

It can be understood that as long as the rotation speed of the spin-coating equipment is 2500-4000 times per minute, the processing time can be implemented within the range of 30-90s. For example, the rotation speed of the spin-coating equipment is set to 3000 times per minute and the processing time is set to 45s.

Based on the above embodiment, in another specific embodiment of the present application, the step of annealing the second spin-coating layer to form the hole transport layer includes:

placing the second spin-coating in an environment of 120-160° C. for annealing for 15 to 30 minutes to form the hole transport layer.

Based on the above embodiments, in a specific embodiment of the present application, the solvent of the saturated solution of 2,9-dimethyl-4,7-biphenyl-1,10-o-diazaphenanthrene may be isopropanol, ethanol or toluene. The solvent of 2,9-dimethyl-4,7-biphenyl-1,10-o-diazaphenanthrene is not particularly limited in this application, and may vary depend on the actual situations.

Based on the above embodiments, in a specific embodiment of the present application, the step of forming a pixel electrode on a substrate further includes:

etching the pixel electrode to form a pixel electrode pattern.

After patterning the pixel electrode, the pixel electrode needs to be cleaned by a method including chemical-cleaning, ultrasonic-cleaning, vacuum-baking, and particle bombardment.

On the basis of the above embodiments, in a specific embodiment of the present application, the step of forming a hole transport layer on the pixel electrode includes:

forming a second spin-coating layer on the pixel electrode by spin-coating a solution of poly(3,4-ethylenedioxythiophene)-poly(styrenesulfonic acid) on the pixel electrode in a spin-coating equipment.

On the basis of the above embodiment, in a specific embodiment of the present application, during the process of spin-coating a solution of poly(3,4-ethylenedioxythiophene)-poly(styrenesulfonic acid) on the pixel electrode in a spin-coating equipment, the spin-coating equipment adopts a rotation speed of 2500-4000 times per minute and a processing time of 40-80s.

On the basis of the above embodiment, in a specific embodiment of the present application, the step of annealing the second spin-coating layer to form the hole transport layer includes:

placing the second spin-coating in an environment of 120-160° C. for annealing for 15 to 30 minutes to form the hole transport layer.

On the basis of the above embodiments, in a specific embodiment of the present application, the step of forming a light-emitting layer on the hole transport layer includes:

forming a third spin-coating layer on the hole transport layer by spin-coating a perovskite precursor solution in a spin-coating equipment; and

annealing the third spin-coating to form the light-emitting layer

On the basis of the above embodiment, in a specific embodiment of the present application, during the process of spin-coating a perovskite precursor solution in a spin-coating equipment, the spin-coating equipment adopts a rotating speed of 2500-5000 times per minute and a processing time of 50-120s.

Based on the above embodiment, in a specific embodiment of the present application, the step of annealing the third spin-coating layer to obtain the light-emitting layer includes:

placing the third spin-coating layer in an environment of 80-120° C. for annealing for 10-60 minutes to form the light-emitting layer.

Based on the above embodiments, in a specific embodiment of the present application, the step of forming a common electrode on the electron transport layer includes:

forming the common electrode on the electron transport layer by vacuum evaporation coating aluminum/lithium fluoride.

Based on the above embodiments, in a specific embodiment of the present application, in the common electrode, a thickness of lithium fluoride is 1 nm, and a thickness of aluminum is 90-120 nm.

In order to better implement the method of manufacturing a light-emitting device according to the embodiments of the present invention, in addition to the method of manufacturing a light-emitting device, an embodiment of the present invention further provides a light-emitting device. The light-emitting device is prepared by the method of manufacturing a light-emitting device according to the above embodiments of the present invention.

As shown in FIG. 2, a schematic structural diagram of a light-emitting device according to an embodiment of the present invention is provided. The light-emitting device includes a pixel electrode ITO 201, a hole transport layer 202, a light-emitting layer 203, an electron transport layer 204, and a common electrode 205.

Specifically, this application does not particularly limit application scenarios of the light-emitting device, which depends on the situation. For example, the light-emitting device can be used in mobile phones, notebook computers, televisions, and various portable display devices.

In order to better implement the light-emitting device in an embodiment of the present invention, based on the light-emitting device, an embodiment of the present invention further provides a display device, which includes the light-emitting device described in the above embodiment.

In the above embodiments, the descriptions of each embodiment have their own emphasis. The parts that are not described in detail in an embodiment can be referred to the detailed descriptions in other embodiments above, which will not be repeated herein for brevity.

In specific implementation, each of the above units or structures may be implemented as independent entities, or may be implemented as any combination as the same or several entities. The specific implementation of the above units or structures can be referred to the foregoing method embodiments, which will not be repeated herein for brevity.

Specific implementation of the foregoing operations can be referred to the foregoing embodiments, and details are not be repeated herein for brevity.

The method of manufacturing a light-emitting device and a light-emitting device provided by the present invention have been described in detail above.

In this article, specific examples are used to explain the principle and implementation of the present invention. The description of the above embodiments is only used to help understand the method of the present invention and its core ideas; meanwhile, various changes and modifications may be suggested to those skilled in the art. The present invention is intended to cover these changes and modifications within the scope of the appended claims. Any modification, equivalent replacement, and improvement made within the spirit and principle of the present invention shall be included in the protection scope of the present invention.

What is claimed is:

1. A method of manufacturing a light-emitting device, comprising:
forming a pixel electrode on a substrate;
forming a hole transport layer on the pixel electrode;
forming a light-emitting layer on the hole transport layer;
forming an electron transport layer on the light-emitting layer by coating a saturated solution of 2,9-dimethyl-4,7-biphenyl-1,10-o-diazaphenanthrene; and
forming a common electrode on the electron transport layer.

2. The method of manufacturing the light-emitting device according to claim 1, wherein the step of forming an electron transport layer on the light-emitting layer by coating a saturated solution of 2,9-dimethyl-4,7-biphenyl-1,10-o-diazaphenanthrene comprises:
forming a first spin-coating layer on the light-emitting layer by spin-coating the 2,9-dimethyl-4,7-biphenyl-1,10-o-diazaphenanthrene saturated solution in a spin-coating equipment; and
annealing the first spin-coating layer to form the electron transport layer.

3. The method of manufacturing the light-emitting device according to claim 2, wherein the step of annealing the first spin-coating layer to form the electron transport layer comprises:
placing the first spin-coating in an environment of 80 to 150° C. for annealing for 10 to 15 minutes to form the electron transport layer.

4. The method of manufacturing the light-emitting device according to claim 2, wherein a solvent of the saturated solution of 2,9-dimethyl-4,7-biphenyl-1,10-o-diazaphenanthrene is isopropanol, ethanol or toluene.

5. The method of manufacturing the light-emitting device according to claim 1, wherein the step of forming a pixel electrode on a substrate further comprises:
etching the pixel electrode to form a pixel electrode pattern.

6. The method of manufacturing the light-emitting device according to claim 1, wherein the step of forming a hole transport layer on the pixel electrode comprises:
forming a second spin-coating layer on the pixel electrode by spin-coating a solution of poly(3,4-ethylenedioxythiophene)-poly(styrenesulfonic acid) on the pixel electrode in a spin-coating equipment; and
annealing the second spin-coating layer to form the hole transport layer.

7. The method of manufacturing the light-emitting device according to claim 6, wherein the step of annealing the second spin-coating layer to form the hole transport layer comprises:
placing the second spin-coating in an environment of 120-160° C. for annealing for 15 to 30 minutes to form the hole transport layer.

8. The method of manufacturing the light-emitting device according to claim 1, wherein the step of forming a light-emitting layer on the hole transport layer comprises:
forming a third spin-coating layer on the hole transport layer by spin-coating a perovskite precursor solution in a spin-coating equipment; and
annealing the third spin-coating to form the light-emitting layer.

9. The method of manufacturing the light-emitting device according to claim 8, wherein the step of annealing the third spin-coating layer to obtain the light-emitting layer comprises:
placing the third spin-coating layer in an environment of 80-120° C. for annealing for 10-60 minutes to form the light-emitting layer.

10. The method of manufacturing the light-emitting device according to claim 1, wherein the step of forming a common electrode on the electron transport layer comprises:
forming the common electrode on the electron transport layer by vacuum evaporation coating aluminum or lithium fluoride.

11. A method of manufacturing a light-emitting device, comprising:
forming a pixel electrode on a substrate;
forming a hole transport layer on the pixel electrode;
forming a light-emitting layer on the hole transport layer;
forming a first spin-coating layer on the light-emitting layer by spin-coating a 2,9-dimethyl-4,7-biphenyl-1,10-o-diazaphenanthrene saturated solution in a spin-coating equipment; and
placing the first spin-coating in an environment of 80 to 150° C. for annealing for 10 to 15 minutes to form an electron transport layer.

12. The method of manufacturing the light-emitting device according to claim 11, wherein a solvent of the saturated solution of 2,9-dimethyl-4,7-biphenyl-1,10-o-diazaphenanthrene is isopropanol, ethanol or toluene.

13. The method of manufacturing the light-emitting device according to claim 11, wherein the step of forming a pixel electrode on a substrate further comprises:
etching the pixel electrode to form a pixel electrode pattern.

14. The method of manufacturing the light-emitting device according to claim 11, wherein the step of forming a hole transport layer on the pixel electrode comprises:
forming a second spin-coating layer on the pixel electrode by spin-coating a solution of poly(3,4-ethylenedioxythiophene)-poly(styrenesulfonic acid) on the pixel electrode in a spin-coating equipment; and
annealing the second spin-coating layer to form the hole transport layer.

15. The method of manufacturing the light-emitting device according to claim 14, wherein the step of annealing the second spin-coating layer to obtain the hole transport layer comprises:
placing the second spin-coating in an environment of 120-160° C. for annealing for 15 to 30 minutes to form the hole transport layer.

16. The method of manufacturing the light-emitting device according to claim 11, wherein the step of forming a light-emitting layer on the hole transport layer comprises:
forming a third spin-coating layer on the hole transport layer by spin-coating a perovskite precursor solution in a spin-coating equipment; and
annealing the third spin-coating to form the light-emitting layer.

17. The method of manufacturing the light-emitting device according to claim 16, wherein the step of annealing the third spin-coating layer to obtain the light-emitting layer comprises:
placing the third spin-coating layer in an environment of 80-120° C. for annealing for 10-60 minutes to form the light-emitting layer.

18. The method of manufacturing the light-emitting device according to claim 11, wherein the step of forming a common electrode on the electron transport layer comprises:
forming the common electrode on the electron transport layer by vacuum evaporation coating aluminum or lithium fluoride.
